(19) United States
(12) Patent Application Publication
(10) Pub. No.: US 2021/0063493 A1
(43) Pub. Date: Mar. 4, 2021

(54) METHOD AND APPARATUS FOR MONITORING A FUEL CELL

(71) Applicant: GM GLOBAL TECHNOLOGY OPERATIONS LLC, Detroit, MI (US)

(72) Inventors: Chad Dubois, Oxford, MI (US); Jie Kou, Novi, MI (US); Manish Sinha, Rochester Hills, MI (US); Xiaofeng Wang, Troy, MI (US)

(73) Assignee: GM GLOBAL TECHNOLOGY OPERATIONS LLC, Detroit, MI (US)

(21) Appl. No.: 16/560,398

(22) Filed: Sep. 4, 2019

(51) Int. Cl. G01R 31/396; H01M 8/04664; H01M 8/04746

(52) U.S. Cl. CPC G01R 31/396; H01M 8/241; H01M 8/04753; H01M 8/04671

(57) ABSTRACT

An anode system is arranged to supply pressurized hydrogen to the anode of a fuel cell, and includes a multi-injector system. A controller is executable to monitor, via a pressure sensor, pressure in the anode system and command actuations of the plurality of hydrogen injectors. The controller may detect a fault in the multi-injector system when the commanded actuations of the plurality of hydrogen injectors are greater than a first threshold and the pressure in the anode system cell is less than a second threshold. The controller may execute alternating actuation of the hydrogen injectors of the multi-injector system and monitor the pressure in the anode system to detect a fault in one of the hydrogen injectors based upon the pressure in the anode system.

### INTRODUCTION

A fuel cell is an electrochemical device that converts chemical energy of a fuel into electrical power by an electro-chemical reaction. The fuel cell includes an anode, a cathode, and an electrolyte that is disposed between the anode and the cathode. During operation, fuel in the form of hydrogen gas may enter the anode and oxygen or air may enter the cathode. The hydrogen gas may dissociate in the anode to generate free hydrogen protons and electrons. The hydrogen protons may then pass through the electrolyte to the cathode, and react with oxygen and electrons in the cathode to generate water. Further, the electrons from the anode may instead be directed through an electrical load to perform work by transforming the electrical power to mechanical power. As such, several fuel cells may be combined to form a fuel cell stack to generate a desired fuel cell power output. For example, a fuel cell for a vehicle may include many stacked fuel cells. One type of fuel cell includes a polymer electrolyte membrane fuel cell (PEMFC).

### SUMMARY

A fuel cell system arranged to supply electric power to an actuator via an electric power circuit is described, and includes an anode and a cathode. An anode system is arranged to supply pressurized hydrogen to the anode of the fuel cell, and includes a multi-injector system including a plurality of hydrogen injectors. A pressure sensor is disposed in the anode system. A controller is operably coupled to the plurality of hydrogen injectors and is in communication with the pressure sensor. The controller includes an instruction set that is executable to monitor, via the pressure sensor, pressure in the anode system and command actuations of the plurality of hydrogen injectors. The controller may detect a fault in the multi-injector system when the commanded actuations of the plurality of hydrogen injectors are greater than a first threshold and the pressure in the anode system cell is less than a second threshold. The controller may execute alternating actuation of the hydrogen injectors of the multi-injector system and monitor, via the pressure sensor, the pressure in the anode system to detect a fault in one of the hydrogen injectors based upon the pressure in the anode system during the alternating actuation of the hydrogen injectors. The controller is able to communicate the detected fault to a second controller.

An aspect of the disclosure includes determining a first time-rate change in the pressure in the anode system during actuation of a first of the hydrogen injectors, and detecting a fault associated with the first of the hydrogen injectors when the first time-rate change in the pressure in the anode system is less than a threshold.

Another aspect of the disclosure includes detecting a fault associated with fluidic flow through the first of the hydrogen injectors when the first time-rate change in the pressure in the anode system is less than a threshold.

Another aspect of the disclosure includes detecting a fault associated with fluidic flow through the first of the hydrogen injectors, which includes detecting a fault associated with the first of the hydrogen injectors when the first time-rate change in the pressure in the anode system is negative.

Another aspect of the disclosure includes determining a first time-rate change in the pressure in the anode system during actuation of a first of the hydrogen injectors, determining a second time-rate change in the pressure in the anode system during actuation of a second of the hydrogen injectors, comparing the first and second time-rate changes in the pressure in the anode system, and detecting a fault associated with one of the first and second hydrogen injectors based upon the comparing of the first and second time-rate changes in the pressure in the anode system.

Another aspect of the disclosure includes detecting a fault associated with the first hydrogen injector when the first time-rate change of the pressure in the anode system is less than the second time-rate change in the pressure in the anode system.

Another aspect of the disclosure includes determining a maximum permissible pressure in the anode system based upon the fault in the multi-injector system, determining a maximum allowable electrical power output from the fuel cell based upon the maximum permissible pressure in the anode system, and controlling the electric load circuit to transfer electric power that is limited to the maximum allowable electrical power output from the fuel cell.

Another aspect of the disclosure includes the fuel cell system being arranged to supply electric power via the external power circuit to an actuator, and controlling the actuator based upon the maximum allowable electrical power output from the fuel cell.

Another aspect of the disclosure includes monitoring, via the pressure sensor, a pressure in the anode system between the multi-injector system and the anode.

The above features and advantages, and other features and advantages, of the present teachings are readily apparent from the following detailed description of some of the best modes and other embodiments for carrying out the present teachings, as defined in the appended claims, when taken in connection with the accompanying drawings.

### BRIEF DESCRIPTION OF THE DRAWINGS

One or more embodiments will now be described, by way of example, with reference to the accompanying drawings, in which:

FIG. 1 schematically illustrates a fuel cell and associated controller, in accordance with the disclosure.

FIG. 2 schematically illustrates an executable control routine for monitoring an embodiment the fuel cell that is described with reference to FIG. 1, in accordance with the disclosure.

FIGS. 3 and 4 graphically show results including an actual pressure of hydrogen in an anode system of a fuel cell and associated with alternating actuation control of an embodiment of the first and second hydrogen injectors of a multi-injector system, in accordance with the disclosure.

The appended drawings are not necessarily to scale, and may present a somewhat simplified representation of various preferred features of the present disclosure as disclosed herein, including, for example, specific dimensions, orientations, locations, and shapes. Details associated with such features will be determined in part by the particular intended application and use environment.

### DETAILED DESCRIPTION

The components of the disclosed embodiments, as described and illustrated herein, may be arranged and designed in a variety of different configurations. Thus, the following detailed description is not intended to limit the scope of the disclosure, as claimed, but is merely representative of possible embodiments thereof. In addition, while numerous specific details are set forth in the following description in order to provide a thorough understanding of the embodiments disclosed herein, some embodiments can be practiced without some of these details. Moreover, for the purpose of clarity, certain technical material that is understood in the related art has not been described in detail in order to avoid unnecessarily obscuring the disclosure. Furthermore, the drawings are in simplified form and are not to precise scale. For purposes of convenience and clarity, directional terms such as top, bottom, left, right, up, over, above, below, beneath, rear, and front, may be used with respect to the drawings. These and similar directional terms are not to be construed to limit the scope of the disclosure. Furthermore, the disclosure, as illustrated and described herein, may be practiced in the absence of an element that is not specifically disclosed herein.

Furthermore, the following detailed description is merely exemplary in nature and is not intended to limit the application and uses. Furthermore, there is no intention to be bound by any expressed or implied theory presented herein. It should be understood that throughout the drawings, corresponding reference numerals indicate like or corresponding parts and features. As used herein, the term system or module may refer to combinations or collections of mechanical and electrical hardware, software, firmware, electronic control component, processing logic, and/or processor device, individually or in combination, including without limitation: application specific integrated circuit (ASIC), an electronic circuit, a processor (shared, dedicated, or group) that executes one or more software or firmware programs, memory to contain software or firmware instructions, a combinational logic circuit, and/or other suitable components that provide the described functionality.

Exemplary embodiments may be described herein in terms of functional and/or logical block components and various processing steps. It should be appreciated that such block components may be realized by any number, combination or collection of mechanical and electrical hardware, software, and/or firmware components configured to perform the specified functions. For example, an embodiment may employ various combinations of mechanical components and electrical components, integrated circuit components, memory elements, digital signal processing elements, logic elements, look-up tables, or the like, which may carry out a variety of functions under the control of one or more microprocessors or other control devices. In addition, those skilled in the art will appreciate that the exemplary embodiments may be practiced in conjunction with a number of mechanical and/or electronic systems, and that the vehicle systems described herein are merely exemplary embodiment of possible implementations. It should be noted that many alternative or additional functional relationships or physical connections may be present in one or more embodiments. As employed herein, the term “upstream” and related terms refer to elements that are towards an origination of a flow stream relative to an indicated location, and the term “downstream” and related terms refer to elements that are away from an origination of a flow stream relative to an indicated location.

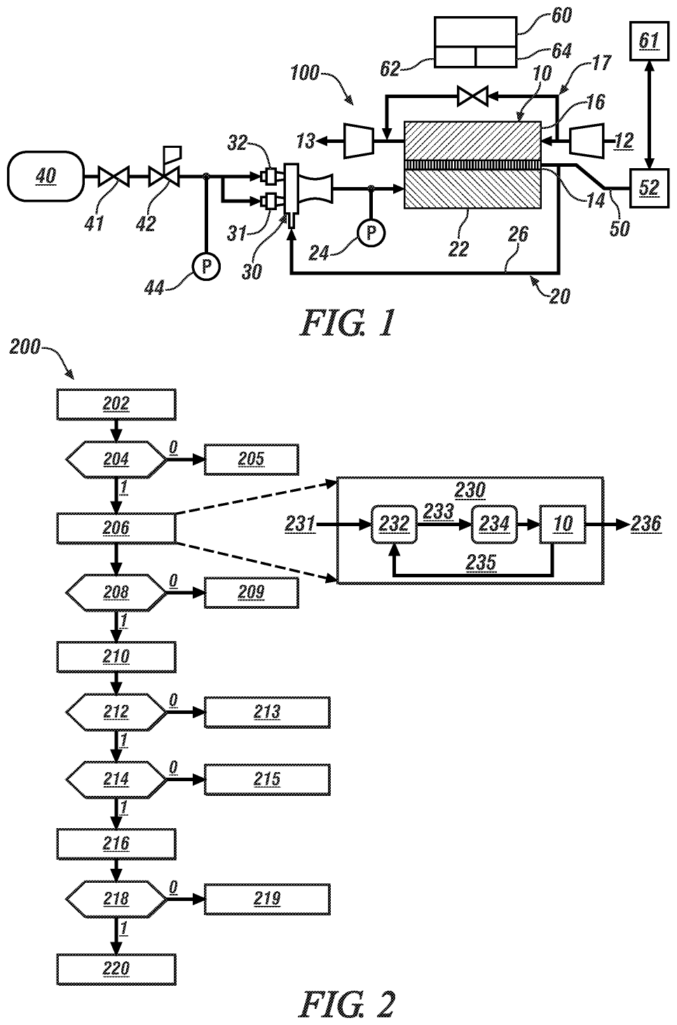

FIG. 1, consistent with embodiments disclosed herein, schematically illustrates a fuel cell system 100 and associated controller 60 are described. The fuel cell system 100 includes, in one embodiment, a fuel cell 10 and an anode system 20. The controller 60 includes an executable control routine 200 for operating the fuel cell system 100, and is described herein with reference to FIG. 2. The fuel cell 10 electrically connects to an external load circuit 50, which may include an electro-mechanical actuator 52. The fuel cell 10 operates as a DC power source for the electro-mechanical actuator 52, which may be an electric machine that may be employed on a mobile platform in the form of a commercial vehicle, industrial vehicle, agricultural vehicle, passenger vehicle, aircraft, watercraft, rail-train, all-terrain vehicle, personal movement apparatus, robot and the like to accomplish the purposes of this disclosure. Alternatively, the fuel cell 10 may be employed as a DC power source for an embodiment of the electro-mechanical actuator 52 that is disposed on a non-vehicular application, such as for stationary power generation, portable power generation, electronics, remote weather station operation, communication centers, and the like.

The fuel cell 10 includes a cathode 16, an anode 22, and an electrolyte 14. The anode system 20 includes a multi-injector system 30 that fluidly couples to the anode 22, and is arranged to controllably supply pressurized hydrogen to an inlet of the anode 22 from a hydrogen tank 40. A first pressure sensor 24 is arranged to monitor pressure in a supply line disposed between the multi-injector system 30 and the anode 22, and a second pressure sensor 44 is arranged to monitor an injector supply pressure, and is arranged in a supply line disposed between the hydrogen tank 40 and the multi-injector system 30, along with a flow regulator 42 and a valve 41. A return line 26 is fluidly coupled between an outlet of the anode 22 and the multi-injector system 30. The fuel cell 10 also includes an air supply system 17 that includes an air inlet 12 and an exhaust 13, and is arranged to supply and control airflow to the cathode 16 of the fuel cell 10. The electrolyte 14, e.g., a polymer electrolyte membrane, is disposed between the cathode 16 and the anode 22. Further, the fuel cell 10 may be formed from one or more membrane electrode assemblies (MEA) that include the cathode 16, anode 22, a plurality of flow plates (not shown), a catalyst (not shown) and a plurality of gas diffusion layers.

The multi-injector system 30 includes, in one embodiment, first and second hydrogen injectors 31, 32, respectively, that are individually controllable to supply pressurized hydrogen to the inlet of the anode 22 from the hydrogen tank 40. Alternatively, the multi-injector system 30 may include three or more injectors that are individually controllable to supply pressurized hydrogen to the inlet of the anode 22 from the hydrogen tank 40.

The controller 60 is arranged to monitor inputs from the first and second pressure sensors 24, 44 and control operations of the first and second hydrogen injectors 31, 32, including as described with reference to the control routine 200 described with reference to FIG. 2. The controller 60 may be arranged to monitor the external load circuit 50, either directly or via communication with a second controller 61 that is arranged to monitor and control the electric machine 52. Alternatively or in addition, the second controller 61 may be arranged to communicate with a device that is capable of human-machine interface, such as an in-vehicle screen, a hand-held device, etc.

During operation of the fuel cell 10, chemical energy from an electrochemical reaction of hydrogen (H₂) and oxygen (O₂) may transform to electrical energy. In particular, hydrogen gas (H₂) may enter the anode 22 and be catalytically split into protons (H⁺) and electrons (e⁺) at a catalyst of the anode 22. The protons (W) may permeate through the electrolyte 14 to the cathode 16, while the electrons (e⁻) may not permeate the electrolyte 14 but may instead travel along an external load circuit to the cathode 16 to produce a fuel cell power output or electrical current, which is supplied to an electric machine 52. Concurrently, air, e.g., oxygen (O₂) and nitrogen (N₂), may enter the cathode 16, react with the protons (W) permeating through the electrolyte 14 and the electrons (e⁻) arriving to the cathode 16 from the external load circuit 50, and form a byproduct such as water (H₂O) and heat. The heat may be expelled through the exhaust 13 of the fuel cell 10. The water (H₂O) may travel through the electrolyte 14 to the anode 22 and may be collected in a sump.

Referring again to FIG. 1, the system and device include the fuel cell 10 and the electric machine 52 that is electrically connected to the fuel cell 10 via the external load circuit 50. Non-limiting examples of the electric machine 52 may include a permanent magnet direct current motor, an alternating current motor, a direct current generator, an alternating current generator, an Eddy current clutch, an Eddy current brake, a rotary converter, a hysteresis dynamometer, a transformer, and the like. For example, the electric machine 52 may be an electric traction motor for a device having an at least partially-electric drivetrain. Motor torque generated by the electric machine 52 may be used to propel a vehicle, start an internal combustion engine, and/or perform other electro-mechanical functions.

In order to perform assigned functions, the controller 60 includes processor 62 and memory 64. The memory 64 may include tangible, non-transitory memory, e.g., read only memory, whether optical, magnetic, flash, or otherwise. The controller 60 may also include sufficient amounts of random access memory, electrically-erasable programmable read only memory, and the like, as well as high-speed clock, analog-to-digital and digital-to-analog circuitry, and input/output circuitry, as well as appropriate signal conditioning and buffer circuitry.

The term “controller” and related terms such as microcontroller, control module, module, control, control unit, processor and similar terms refer to one or various combinations of Application Specific Integrated Circuit(s) (ASIC), Field-Programmable Gate Array (FPGA), electronic circuit(s), central processing unit(s), e.g., microprocessor(s) and associated non-transitory memory component(s) in the form of a high-speed clock and memory/storage devices (read only, programmable read only, random access, hard drive, etc.). The non-transitory memory component is capable of storing machine-readable instructions in the form of one or more software or firmware programs or routines, combinational logic circuit(s), input/output circuit(s) and devices, signal conditioning and buffer circuitry and other components that can be accessed by one or more processors to provide a described functionality. Input/output circuit(s) and devices include analog/digital converters and related devices that monitor inputs from sensors, with such inputs monitored at a preset sampling frequency or in response to a triggering event. Software, firmware, programs, instructions, control routines, code, algorithms and similar terms mean controller-executable instruction sets including calibrations and look-up tables. Each controller executes control routine(s) to provide desired functions. Routines may be executed at regular intervals, for example each 100 microseconds during ongoing operation. Alternatively, routines may be executed in response to occurrence of a triggering event. Communication between controllers, actuators and/or sensors may be accomplished using a direct wired point-to-point link, a networked communication bus link, a wireless link or another suitable communication link. Communication includes exchanging data signals in suitable form, including, for example, electrical signals via a conductive medium, electromagnetic signals via air, optical signals via optical waveguides, and the like. The data signals may include discrete, analog or digitized analog signals representing inputs from sensors, actuator commands, and communication between controllers.

The term “signal” refers to a physically discernible indicator that conveys information, and may be a suitable waveform (e.g., electrical, optical, magnetic, mechanical or electromagnetic), such as DC, AC, sinusoidal-wave, triangular-wave, square-wave, vibration, and the like, that is capable of traveling through a medium.

The terms “calibration”, “calibrated”, and related terms refer to a result or a process that compares an actual or standard measurement associated with a device or system with a perceived or observed measurement or a commanded position for the device or system. A calibration as described herein can be reduced to a storable parametric table, a plurality of executable equations or another suitable form that may be employed as part of a measurement or control routine.

A parameter is defined as a measurable quantity that represents a physical property of a device or other element that is discernible using one or more sensors and/or a physical model. A parameter can have a discrete value, e.g., either “1” or “0”, or can be infinitely variable in value.

As described herein, a method, apparatus, and system are provided for monitoring, detecting, diagnosing, identifying and mitigating a fault associated with one of the hydrogen injectors 31, 32 that control supply of hydrogen to the fuel cell 10. This includes a capability to detect a stuck closed injector, or a partially blocked injector while allowing the system to continue safe operation during and after the detection. The concepts further provide system robustness and detailed service instructions upon detection of other fuel delivery related faults. Remedial action can be executed to prevent hydrogen starvation and related cell reversals and quick stops thus improving durability and reliability of the fuel cell 10 when there is a single injector fault, when there are multiple injector faults with one of the injectors still operational, or when injector flow becomes reduced due to debris contamination, or when the second pressure sensor 44 has an undetectable drift. In addition this includes a capability to isolate which of the multiple hydrogen injectors 31, 32 has experienced a related fault, and identify it to a service technician via an injector-specific diagnostic trouble code.

FIG. 2 illustrates an embodiment of the control routine 200 for monitoring operation of the fuel cell system 100. The control routine 200 is illustrated as a collection of blocks in a logical flow graph, which represents a sequence of operations that can be implemented in hardware, software, or a combination thereof. In the context of software, the blocks represent computer instructions that, when executed by one or more processors, perform the recited operations. For convenience and clarity of illustration, the control routine 200 is described with reference to the fuel cell system 100 that is shown in FIG. 1. Table 1 is provided as a key wherein the numerically labeled blocks and the corresponding functions are set forth as follows, corresponding to the control routine 200.

TABLE 1

| BLOCK | BLOCK CONTENTS |
|---|---|
| 202 | Operate fuel cell; monitor pressures, injector commands |
| 204 | Execute diagnostic routine |
| 205 | No further action |
| 206 | Execute remedial action, including limiting fuel cell current |
| 208 | Is current density less than threshold? |
| 209 | Operate with current limit |
| 210 | Enable alternating injection control |
| 212 | Monitor pressure during alternating injection control |
| 213 | Detect and isolate fault-closed associated with one of the |
| | injectors |
| 214 | Monitor ΔP during alternating injection control |
| 215 | Detect and isolate fault-reduced flow condition associated |
| | with one of the injectors |
| 216 | Limit current output from fuel cell |
| 218 | Monitor first and second pressure sensors |
| 219 | Request service |
| 220 | Monitor anode system |

Execution of the control routine 200 may proceed as follows. The steps of the control routine 200 may be executed in a suitable order, and are not limited to the order described with reference to FIG. 2. As employed herein, the term “1” indicates an answer in the affirmative, or “YES”, and the term “0” indicates an answer in the negative, or “NO”.

The controller 60 executes the control routine 200 during operation of the fuel cell 10. Operation of the fuel cell 10 includes commanding operation of the first and second hydrogen injectors 31, 32 of the multi-injector system 30 to controllably inject pressurized hydrogen into the inlet of the anode 22 via the anode system 20. The first and second hydrogen injectors 31, 32 may be controlled at a pulsewidth-modulated duty cycle (PWM-DC), wherein the magnitude of the PWM-DC is selected to achieve a desired pressure setpoint (dSP) in the anode system 20. The desired pressure setpoint (dSP) is determined based upon a desired electrical power output that is delivered from the fuel cell 10 to the electro-mechanical actuator 52 via the external load circuit 50. The first pressure sensor 24 monitors the pressure in the supply line disposed between the multi-injector system 30 and the anode 22, and the second pressure sensor 24 is arranged to monitor pressure in a supply line disposed between the hydrogen tank 40 and the multi-injector system 30. As such, the controller 60 monitors the PWM-DC to the first and second hydrogen injectors 31, 32, and also monitors the pressure that is output from the first pressure sensor 24 (202).

A diagnostic routine (204) is periodically executed, which includes evaluating the PWM-DC and evaluating the pressure of hydrogen that is being supplied to the anode system 20. In one embodiment, evaluating the pressure of hydrogen that is being supplied to the anode system 20 includes evaluating the pressure that is output from the first pressure sensor 24 in relation to the desired pressure setpoint (dSP), e.g., by determining a difference between the pressure that is output from the first pressure sensor 24 and the desired pressure setpoint (dSP). Alternatively, evaluating the pressure of hydrogen that is being supplied to the anode system 20 may include evaluating the absolute value of the pressure that is output from the first pressure sensor 24.

When the PWM-DC is less than an upper value, e.g., is less than 90%, or when the difference between the pressure output from the first pressure sensor 24 and the desired pressure setpoint (dSP) is less than a calibrated value, e.g., is less than 10 kPa (204)(0), the diagnostic routine determines that the fuel cell 10 is operating in accordance with specification, and this iteration of the control routine 200 ends without further action (205).

When the PWM-DC is greater than the upper value, e.g., is greater than 90%, and when the difference between the pressure output from the first pressure sensor 24 and the desired pressure setpoint (dSP) is greater than the calibrated value, e.g., is greater than 10 kPa (204)(1), the diagnostic routine determines that a fault in the anode system 20 may exist along with a need to execute remedial action (206).

The remedial action (206) may be in the form of limiting current output from the fuel cell 10 via a remedial fuel cell control routine 230. The remedial fuel cell control routine 230 may include estimating or otherwise determining a maximum flowrate of hydrogen that can be supplied to the anode system 20 via the multi-injector system 30 based upon an analysis of the detected fault, and determining a maximum allowable electrical power in the form of a maximum allowable current 233 for operating the fuel cell 10 based upon the maximum flowrate of hydrogen. Operation of the multi-injector system 30 is controlled to control the pressure of hydrogen that is being supplied to the anode system 20 to a maximum pressure setpoint (SPmax) 231 in the inlet of the anode 22 via the anode system 20, taking into account the present operating characteristics of the fuel cell 10.

The SPmax 231 is provided as input to a remedial fuel cell control routine 230. The remedial fuel cell control routine 230 includes a closed-loop feedback control system that includes a PI (proportional-integral) controller 232 and a power management controller 234 that are arranged to control the fuel cell 10. The PI controller 232 determines the maximum allowable current 233 for operating the fuel cell 10, and determines the SPmax 231 based thereon, taking into account pressure feedback 235 from the first pressure sensor 24. The maximum allowable current 233 is input to the power management controller 234, which controls operation of the fuel cell 10 by limiting an electrical power demand 236 therefrom. The operation of the remedial fuel cell control routine 230 is intended to prevent hydrogen starvation within the fuel cell 10 and thus avoid cell reversal or another operation that may lead to internal damage of the fuel cell 10.

In conjunction with and after implementing the remedial action (206), a current density (A/mm²) output from the fuel cell 10 is determined and evaluated by comparing it with a minimum threshold, which is calibratable (208).

When the current density is greater than the minimum threshold (208)(0), operation of the fuel cell 10 is commanded to continue operation with the current being limited based upon the remedial fuel cell control routine 230 (209), and this iteration of the routine 200 ends.

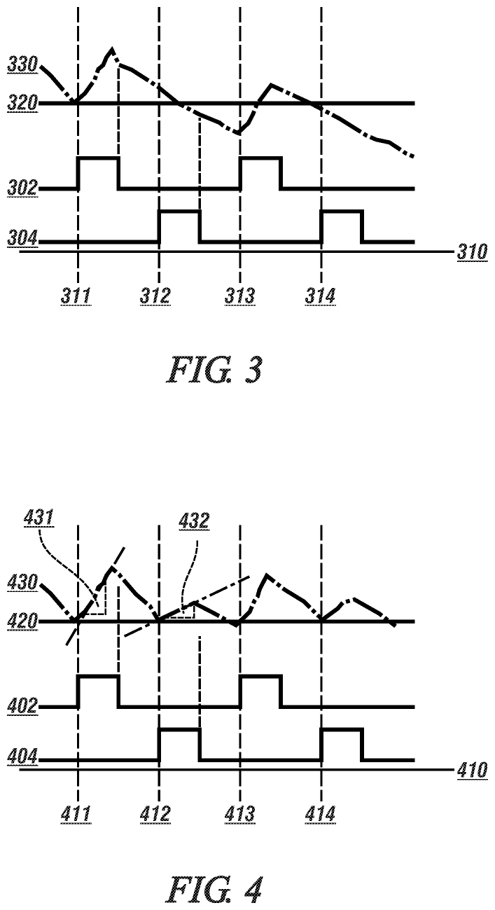

When the current density is less than the minimum threshold (208)(1), further action is immediately requested, and includes executing an alternating actuation control of the first and second hydrogen injectors 31, 32 of the multi-injector system 30, with both the first and second hydrogen injectors 31, 32 being controlled at a common duty cycle. During the alternating actuation control of the first and second hydrogen injectors 31, 32, the first pressure sensor 24 monitors the pressure in the anode system 20 of the fuel cell 10 (210). The alternating actuation control of the first and second hydrogen injectors 31, 32 is shown graphically in both FIGS. 3 and 4.

Referring again to FIG. 2, during actuation of each of the first and second hydrogen injectors 31, 32, the first pressure sensor 24 monitors the pressure in the anode system 20 of the fuel cell 10, including detecting a change in pressure that corresponds to the actuation of either the first or the second hydrogen injector 31, 32 (212). This operation is shown graphically with reference to FIG. 3.

Referring again to FIG. 2, when there is no or minimal change in pressure corresponding to the actuation of one or the other of the first or the second hydrogen injectors 31, 32 (212)(0), a fault may be detected that is associated with the corresponding one of the first or the second hydrogen injectors 31, 32 that exhibits no or minimal change in pressure during the actuation (213). Further action may include setting a fault indicator lamp and an associated diagnostic code that identifies the corresponding one of the first or the second hydrogen injectors 31, 32, and executing other remedial action to limit operation of the fuel cell 10 to mitigate damage.

When there is at least a minimal change in pressure corresponding to the actuation of both the first or the second hydrogen injectors 31, 32 (212)(1), further action includes evaluating time-rate changes in the pressure in the anode system 20 during actuations of the first and the second hydrogen injectors 31, 32. In one embodiment, evaluating the time-rate changes in the pressure in the anode system 20 during the actuations of the first and the second hydrogen injectors 31, 32 includes comparing the first and second time-rate changes in the pressure in the anode system 20 to detect whether the first and second time-rate changes in the pressure are the same (214).

When there is a difference between the first and second time-rate changes in the pressure (214)(0), the first and second time-rate changes in the pressure in the anode system 20 are evaluated to identify which of the first and the second hydrogen injectors 31, 32 has a reduction in flow of hydrogen, as indicated by a lower value for the time-rate change in pressure in the anode system 20 (215). This result is depicted graphically with reference to FIG. 4. A fault may be detected that is associated with the corresponding one of the first or the second hydrogen injectors 31, 32 that exhibits the lower value of the time-rate change in pressure during the actuation. Further action may include setting a fault indicator lamp and an associated diagnostic code that identifies the corresponding one of the first or the second hydrogen injectors 31, 32, and executing other remedial action to limit operation of the fuel cell 10 to mitigate damage.

When the first and second time-rate changes in the pressure in the anode system 20 are the same (214)(1), a diagnostic code may be set that indicates a need for service, and operation of the fuel cell 10 is commanded to continue with the current being limited based upon the remedial fuel cell control routine 230 (216).

Further action can include monitoring the second pressure sensor 44 to detect occurrence of a fault (218), with service being requested via the second controller 61 (219) as needed.

Further action can include monitoring the portion of the anode system 20 that is upstream of the multi-injector system 30 to verify pressure and flow are in accordance with specification (220).

Referring now to FIG. 3, with continued reference to the fuel cell 10 and associated controller 60 described with reference to FIG. 1 and the executable control routine 200 described with reference to FIG. 2, actual pressure of hydrogen 330 that is being supplied to the anode system 20 as measured by the first pressure sensor 24 are shown in response to alternating actuation control of an embodiment of the first and second hydrogen injectors 31, 32 of the multi-injector system 30, with both the first and second hydrogen injectors 31, 32 being controlled at a common duty cycle. Time is indicated with reference to the horizontal axis 310.

Actuation commands 302 for the first hydrogen injector 31 are indicated at timepoints 311 and 313, and actuation commands 304 for the second hydrogen injector 32 are indicated at timepoints 312 and 314. Also shown is an actual pressure of hydrogen that is being supplied to the anode system 20 as measured by the first pressure sensor 24 (330) in relation to a desired pressure setpoint (dSP) (320). As indicated by Line 330, an increase in the actual pressure of hydrogen 330 corresponds to the actuation commands 302 for the first hydrogen injector 31, which indicates that there is flow of hydrogen from the first hydrogen injector 31. However, as indicated by Line 330, there is a decrease in the actual pressure of hydrogen 330 corresponding to the actuation commands 304 for the second hydrogen injector 32, which indicates that there is minimal or no flow of hydrogen from the second hydrogen injector 32. This information can be employed by the controller 60 to isolate a fault to one of the injectors, for example to the second hydrogen injector 32 in this instance.

Referring now to FIG. 4, with continued reference to the fuel cell 10 and associated controller 60 described with reference to FIG. 1 and the executable control routine 200 described with reference to FIG. 2, actual pressure of hydrogen 430 that is being supplied to the anode system 20 as measured by the first pressure sensor 24 are shown in response to alternating actuation control of an embodiment of the first and second hydrogen injectors 31, 32 of the multi-injector system 30, with both the first and second hydrogen injectors 31, 32 being controlled at a common duty cycle. Time is indicated with reference to the horizontal axis 410.

Actuation commands 402 for the first hydrogen injector 31 are indicated at timepoints 411 and 413, and actuation commands 404 for the second hydrogen injector 32 are indicated at timepoints 412 and 414. Also shown is an actual pressure of hydrogen that is being supplied to the anode system 20 as measured by the first pressure sensor 24 (430) in relation to a desired pressure setpoint (dSP) (420). As indicated by Line 430, an increase in the actual pressure of hydrogen 430 corresponds to the actuation commands 402 for the first hydrogen injector 31, which indicates that there is flow of hydrogen from the first hydrogen injector 31, with a corresponding first time-rate change in the actual pressure 431. As indicated by Line 430, there is an increase in the actual pressure of hydrogen 430 corresponding to the actuation commands 404 for the second hydrogen injector 32, with a corresponding second time-rate change in the actual pressure 432. However there is a significant difference between the first time-rate change in the actual pressure 431 and the second time-rate change in the actual pressure 432, which indicates that there is some form of flow blockage associated with the second hydrogen injector 32. This information can be employed by the controller 60 to isolate a fault to one of the injectors, for example to the second hydrogen injector 32 in this instance.

Embodiment of the concepts described herein provide diagnostic and remedial action for preventing hydrogen starvation, related cell reversals and occurrence of quick stop events during operation, and thus improve durability and reliability when a fault associated with one of the hydrogen injectors 31, 32 occurs, and when there is a reduction in flowrate from one of the hydrogen injectors due to debris contamination or when there is an undetected drift in the second pressure sensor 44 monitoring the injector supply pressure. This permits continued operation of the fuel cell 10, albeit with a reduction in maximum electrical power output. Such operation may prevent damage and improve durability thereof. Such operation may include adjusting an effective area of the injectors, which may be used in a feedforward control system to allow continued operation of the electro-mechanical actuator 52 while minimizing or preventing likelihood of occurrence of damage.

The flowchart and block diagrams in the flow diagrams illustrate the architecture, functionality, and operation of possible implementations of systems, methods, and computer program products according to various embodiments of the present disclosure. In this regard, each block in the flowchart or block diagrams may represent a module, segment, or portion of code, which comprises one or more executable instructions for implementing the specified logical function(s). It will also be noted that each block of the block diagrams and/or flowchart illustrations, and combinations of blocks in the block diagrams and/or flowchart illustrations, may be implemented by dedicated-function hardware-based systems that perform the specified functions or acts, or combinations of dedicated-function hardware and computer instructions. These computer program instructions may also be stored in a computer-readable medium that can direct a computer or other programmable data processing apparatus to function in a particular manner, such that the instructions stored in the computer-readable medium produce an article of manufacture including instruction set that implements the function/act specified in the flowchart and/or block diagram block or blocks.

The detailed description and the drawings or figures are supportive and descriptive of the present teachings, but the scope of the present teachings is defined solely by the claims. While some of the best modes and other embodiments for carrying out the present teachings have been described in detail, various alternative designs and embodiments exist for practicing the present teachings defined in the appended claims.

What is claimed is:

1. A method for monitoring a fuel cell system including a fuel cell and an anode system that are arranged to supply electric power to an external load circuit, the method comprising:
monitoring, via a pressure sensor, pressure in the anode system, wherein the anode system includes a multi-injector system including a plurality of hydrogen injectors arranged to supply pressurized hydrogen to an anode of the fuel cell;
monitoring actuation commands to the plurality of hydrogen injectors;
detecting a fault in the multi-injector system when the actuation commands to the plurality of hydrogen injectors are greater than a first threshold and the pressure in the anode system is less than a second threshold;
executing an alternating actuation of the hydrogen injectors of the multi-injector system and monitoring, via the pressure sensor, pressure in the anode system; and
detecting a fault in one of the hydrogen injectors of the multi-injector system based upon the pressure in the anode system during the alternating actuation of the hydrogen injectors.

2. The method of claim 1, further comprising communicating the fault detected in the one of the hydrogen injectors to a second controller.

3. The method of claim 1, wherein detecting the fault in one of the hydrogen injectors of the multi-injector system based upon the pressure in the anode system during the alternating actuation of the hydrogen injectors comprises:
determining a first time-rate change in the pressure in the anode system during actuation of a first of the hydrogen injectors; and
detecting a fault associated with the first of the hydrogen injectors when the first time-rate change in the pressure in the anode system is less than a third threshold.

4. The method of claim 3, wherein detecting the fault associated with the first of the hydrogen injectors when the first time-rate change in the pressure in the anode system is less than the third threshold comprises detecting a fault associated with fluidic flow through the first of the hydrogen injectors.

5. The method of claim 1, wherein detecting the fault in one of the hydrogen injectors of the multi-injector system based upon the pressure in the anode system during the alternating actuation of the hydrogen injectors comprises:
determining a first time-rate change in the pressure in the anode system during actuation of a first of the hydrogen injectors; and
detecting a fault associated with the first of the hydrogen injectors when the first time-rate change in the pressure in the anode system is negative.

6. The method of claim 5, wherein detecting the fault associated with the first of the hydrogen injectors when the first time-rate change in the pressure in the anode system is negative comprises detecting a fault in the first of the hydrogen injectors.

7. The method of claim 1, wherein detecting the fault in one of the hydrogen injectors of the multi-injector system based upon the pressure in the anode system during the alternating actuation of the hydrogen injectors comprises:
determining a first time-rate change in the pressure in the anode system during actuation of a first of the hydrogen injectors;
determining a second time-rate change in the pressure in the anode system during actuation of a second of the hydrogen injectors;
comparing the first and second time-rate changes in the pressure in the anode system; and
detecting a fault associated with one of the first and second hydrogen injectors based upon the comparing of the first and second time-rate changes in the pressure in the anode system.

8. The method of claim 7, wherein detecting the fault associated with one of the first and second hydrogen injectors based upon the comparing of the first and second time-rate changes in the pressure in the anode system comprises detecting a fault associated with the first hydrogen injector when the first time-rate change of the pressure in the anode system is less than the second time-rate change in the pressure in the anode system.

9. The method of claim 1, further comprising:
determining a maximum hydrogen flowrate into the anode system based upon the fault in the multi-injector system;
determining a maximum allowable electrical power output from the fuel cell based upon the maximum hydrogen flowrate into the anode system; and
controlling the external load circuit to transfer electric power, wherein the electric power is limited to the maximum allowable electrical power output from the fuel cell.

10. The method of claim 9, wherein the fuel cell system is arranged to supply electric power via the external power circuit to an actuator; wherein the method further comprises controlling the actuator based upon the maximum allowable electrical power output from the fuel cell.

11. The method of claim 1, wherein monitoring, via the pressure sensor, pressure in the anode system comprises monitoring, via the pressure sensor, pressure in the anode system between the multi-injector system and the anode.

12. A fuel cell system arranged to supply electric power to an electric power circuit, comprising:
an anode system including a multi-injector system including a plurality of hydrogen injectors arranged to supply pressurized hydrogen to an anode of a fuel cell;
a pressure sensor disposed in the anode system; and
a controller operably coupled to the plurality of hydrogen injectors and in communication with the pressure sensor, the controller including an instruction set, the instruction set executable to:
monitor, via the pressure sensor, pressure in the anode system;
command actuations of the plurality of hydrogen injectors;
detect a fault in the multi-injector system when the commanded actuations of the plurality of hydrogen injectors are greater than a first threshold and the pressure in the anode system is less than a second threshold;
execute an alternating actuation of the hydrogen injectors of the multi-injector system and monitor, via the pressure sensor, pressure in the anode system; and
detect a fault in one of the hydrogen injectors of the multi-injector system based upon the pressure in the anode system during the alternating actuation of the hydrogen injectors.

13. The fuel cell system of claim 12, wherein the instruction set executable to detect the fault in one of the hydrogen injectors of the multi-injector system based upon the pressure in the anode system during the alternating actuation of the hydrogen injectors comprises the instruction set executable to:
determine a first time-rate change in the pressure in the anode system during actuation of a first of the hydrogen injectors; and
detect a fault associated with the first of the hydrogen injectors when the first time-rate change in the pressure in the anode system is less than a threshold.

14. The fuel cell system of claim 12, wherein the instruction set executable to detect the fault in one of the hydrogen injectors of the multi-injector system based upon the pressure in the anode system during the alternating actuation of the hydrogen injectors comprises the instruction set executable to:
determine a first time-rate change in the pressure in the anode system during actuation of a first of the hydrogen injectors; and
detect a fault associated with the first of the hydrogen injectors when the first time-rate change in the pressure in the anode system is negative.

15. The fuel cell system of claim 12, wherein the instruction set executable to detect the fault in one of the hydrogen injectors of the multi-injector system based upon the pressure in the anode system during the alternating actuation of the hydrogen injectors comprises the instruction set executable to:
determine a first time-rate change in the pressure in the anode system during actuation of a first of the hydrogen injectors;
determine a second time-rate change in the pressure in the anode system during actuation of a second of the hydrogen injectors;
compare the first and second time-rate changes in the pressure in the anode system; and
detect a fault associated with one of the first and second hydrogen injectors based upon the comparison of the first and second time-rate changes in the pressure in the anode system.

16. A method for monitoring a fuel cell system arranged to supply electric power to an external load circuit, the method comprising:
monitoring, via a pressure sensor, pressure in an anode system, wherein the anode system includes a multi-injector system including a plurality of hydrogen injectors arranged to supply pressurized hydrogen to an anode of the fuel cell;
monitoring actuation commands to the plurality of hydrogen injectors to control flow of hydrogen into the anode system, wherein the actuation commands include a pulsewidth-modulated duty cycle command;
detecting a fault in the multi-injector system when the pulsewidth-modulated duty cycle commands to the plurality of hydrogen injectors are greater than a first threshold and the pressure in the anode system is less than a second threshold;
executing an alternating actuation of the hydrogen injectors of the multi-injector system and monitoring, via the pressure sensor, pressure in the anode system;
detecting a fault in one of the hydrogen injectors of the multi-injector system based upon the pressure in the anode system during the alternating actuation of the hydrogen injectors; and
communicating the fault detected in the one of the hydrogen injectors to a second controller.

17. The method of claim 16, wherein detecting the fault in the one of the hydrogen injectors of the multi-injector system based upon the pressure in the anode system during the alternating actuation of the hydrogen injectors comprises:
determining a first time-rate change in the pressure in the anode system during actuation of a first of the hydrogen injectors; and
detecting a fault associated with fluidic flow through the first of the hydrogen injectors when the first time-rate change in the pressure in the anode system is less than a threshold.

18. The method of claim 16, wherein detecting the fault in one of the hydrogen injectors of the multi-injector system based upon the pressure in the anode system during the alternating actuation of the hydrogen injectors comprises:
determining a first time-rate change in the pressure in the anode system during actuation of a first of the hydrogen injectors; and
detecting a fault associated with the first of the hydrogen injectors when the first time-rate change in the pressure in the anode system is negative.

19. The method of claim 16, wherein detecting the fault in one of the hydrogen injectors of the multi-injector system based upon the pressure in the anode system during the alternating actuation of the hydrogen injectors comprises:
determining a first time-rate change in the pressure in the anode system during actuation of a first of the hydrogen injectors;
determining a second time-rate change in the pressure in the anode system during actuation of a second of the hydrogen injectors;
comparing the first and second time-rate changes in the pressure in the anode system; and
detecting a fault associated with one of the first and second hydrogen injectors based upon the comparing of the first and second time-rate changes in the pressure in the anode system.

20. The method of claim 19, wherein detecting the fault associated with one of the first and second hydrogen injectors based upon the comparing of the first and second time-rate changes in the pressure in the anode system comprises detecting a fault associated with the first hydrogen injector when the first time-rate change of the pressure in the anode system is less than the second time-rate change in the pressure in the anode system.
